(19) United States
(12) Patent Application Publication
(10) Pub. No.: US 2009/0053864 A1
(43) Pub. Date: Feb. 26, 2009

(54) METHOD FOR FABRICATING A SEMICONDUCTOR STRUCTURE HAVING HETEROGENEOUS CRYSTALLINE ORIENTATIONS

(76) Inventors: Jinping Liu, Singapore (SG); Alex K.H. See, Singapore (SG); Mei Sheng Zhou, Singapore (SG); Liang Choo Hsia, Singapore (SG)

Correspondence Address: BRINKS HOFER GILSON & LIONE, P.O. BOX 10395, CHICAGO, IL, 60610, US

(21) Appl. No.: 11/844,074

(22) Filed: Aug. 23, 2007

(51) Int. Cl. H01L 21/8238

(52) U.S. Cl. 438/198; 257/E21.632

(57) ABSTRACT

A method for fabricating a semiconductor structure having heterogeneous crystalline orientations by forming a region including a semiconductor material having a specified crystalline orientation using an epitaxial buffer overlying a semiconductor substrate. The buffer provides a transfer body such that the semiconductor material has a crystalline orientation that differs from the crystalline orientation of a semiconductor region underlying the buffer. The method also includes fabricating a semiconductor structure having a p-type device region and an n-type device region, where a supporting semiconductor substrate is either n-type or p-type and where the semiconductor material is separated from the substrate by a buffer and has a crystalline orientation that differs from the crystalline orientation of the substrate.

### TECHNICAL FIELD

The present invention relates, generally, to the fabrication of semiconductor layers having different crystalline orientations along a common surface and, more particularly, to methods for fabricating a semiconductor surface having heterogeneous crystalline orientations using epitaxial processes.

### BACKGROUND

The trend in semiconductor process technology is toward higher speed devices that can be fabricated in substrates having heterogeneous structures. For example, silicon-on-insulator substrates have been developed that provide a thin surface layer upon which active devices are fabricated. Several fabrication techniques have been developed to provide substrates having a thin film overlying a buried insulating layer. Such process techniques include implantation of oxygen into a substrate known as “SIMOX” and implantation followed by fracturing and lift off, known as “SMARTCUT”. The object of substrate fabrication using processes such as SIMOX and SMARTCUT is to produce a very thin homogeneous layer overlying a buried insulating structure. While high speed devices can be formed in the homogeneous thin film, further refinement and substrate processing can lead to even higher speed devices.

Conventional silicon processing technology has developed to form metal-oxide-semiconductor (MOS) devices having both n-type and p-type conductivity. Such devices are commonly fabricated in integrated circuits employing complementary-metal-oxide-semiconductor (CMOS) technology. A wide variety of devices can beneficially employ CMOS technology, including RF analog devices, memory devices, microprocessor devices, and the like.

To improve the performance of n-type and p-type transistors, substrates are provided having heterogeneous crystalline orientations that are known to increase the carrier mobility of either an n-type transistor or a p-type transistor. For example, in silicon substrate technology, it is known that electron mobility is higher on silicon having a (100) or (001) crystalline orientation, while hole mobility is higher on a silicon surface having a (110) surface.

The fabrication of a substrate surface having differing crystalline orientations on the same surface requires advanced process technology and producing a defect-tree surface has prove problematic and expensive. In one such technique, silicon wafers are bonded together where one wafer has a (100) orientation and the other wafer has a (110) orientation. After bonding, the (110) wafer is masked and etched to expose portions of the underlying (100) wafer. Then, an epitaxial deposition process is carried out to grow (100) silicon on the exposed underlying wafer surface.

Another substrate fabrication process includes depositing dielectric layers on a silicon substrate having a (100) orientation. Then, silicon having a (110) orientation is deposited onto the dielectric layers. Next, an additional dielectric layer is formed over the (110) silicon and a resist pattern is form on the dielectric layer. The stack including the (110) silicon and adjacent dielectric layers is etched back to expose portions of the underlying (100) silicon surface. An epitaxial silicon deposition process is carried out to grow (100) silicon on the exposed portions of the underlying silicon surface.

While the existing substrate fabrication processes provide a substrate surface having a heterogeneous crystalline orientation, they require numerous processing steps that increase the possibility of contamination and require precise lithographic and etching techniques. Accordingly, a need existed for an improved method to fabricate semiconductor structures having heterogeneous crystalline orientation.

### SUMMARY

In one embodiment, a method for fabricating a semiconductor structure having heterogeneous crystalline orientations includes providing a first region including a semiconductor material having a first crystalline orientation. An epitaxial buffer is formed on the first semiconductor region and a second region of the semiconductor material is formed on the buffer layer. The second region of semiconductor material has a second crystalline orientation that differs from the first crystalline orientation.

In another embodiment, a method for fabricating a semiconductor layer includes providing a semiconductor substrate having a fist crystalline orientation. A first crystalline dielectric layer is formed on the semiconductor substrate, where the first crystalline dielectric layer has the same crystalline orientation as the semiconductor substrate. A second crystalline dielectric layer is formed on the first crystalline dielectric layer. A semiconductor region is formed on the second crystalline dielectric layer, where the semiconductor region has a second crystalline orientation different from the first crystalline orientation.

In yet another embodiment, a method for fabricating a semiconductor layer includes providing a semiconductor substrate having a first device region of a first conductivity type and a second device region of a second conductivity type, where the semiconductor substrate has a first crystalline orientation. A buffer is formed on at least the p-type device region and a semiconductor layer is formed on the buffer. The semiconductor layer has a second crystalline orientation different from the first crystalline orientation.

### BRIEF DESCRIPTION OF THE DRAWING

FIGS. 1-3 are cross-sectional views illustrating processing steps in accordance with an embodiment of the invention; and

FIG. 4 illustrates a semiconductor structure fabricated in accordance with an embodiment of the invention.

### DETAILED DESCRIPTION

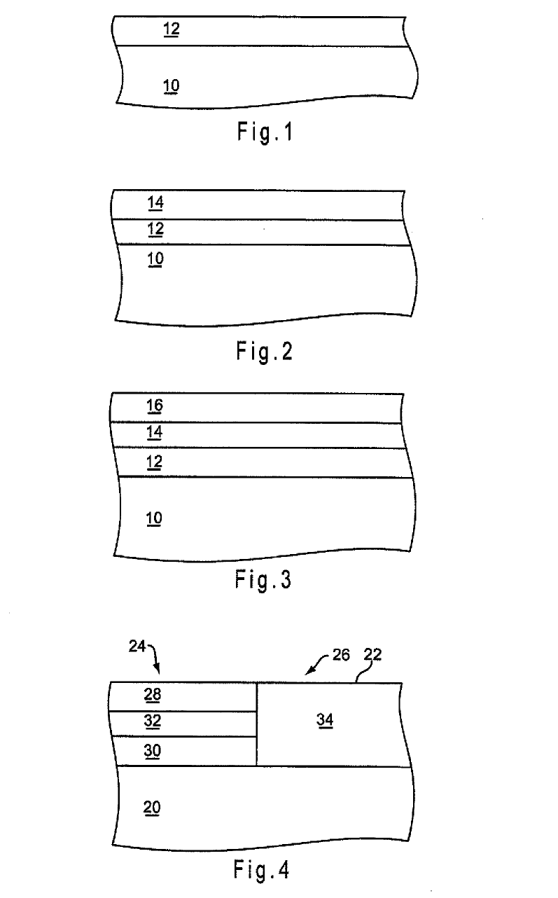

FIG. 1 illustrates in cross-section, a semiconductor substrate 10 having a first buffer layer 12 thereon. Semiconductor substrate 10 is a semiconductor material having a particular crystalline orientation. In one embodiment of the invention, semiconductor substrate 10 is single crystal silicon. In another embodiment, semiconductor substrate 10 is a group III-IV semiconductor material. In yet another embodiment, semiconductor substrate 10 is gallium arsenide. Additional semiconductor materials, such as germanium and the like are also contemplated. For purposes of illustrating the fabrication process of the invention, semiconductor substrate 10 will be assumed to be single crystal silicon having a (001) crystalline orientation. Although the following description will be set forth in relation to a single crystal silicon substrate, those skilled in the art will recognize that the inventive process can be carried out with many different semiconductor materials including, without limitation, those materials described above.

First buffer layer 12 is preferably a crystalline oxide material epitaxially deposited onto the surface of semiconductor substrate 10. In accordance with the invention, first buffer layer 12 can be any of a number of different crystalline oxide material that will establish a crystalline orientation matching that of semiconductor substrate 10. In one embodiment, the crystalline oxide material is formed by laser molecular beam epitaxy in which successive model layers of crystalline oxide material are formed at reduced pressure and at temperatures in excess of 500° C. Where semiconductor substrate 10 is single crystal silicon, preferred materials for first buffer layer 12 including yittria-stabilized-zirconia (YSZ), SrO, MgO, ZrO₂, and combinations thereof, and the like. These crystalline oxide materials are epitaxially grown, such that their crystalline lattice structure substantially matches that of the underlying silicon substrate and no amorphous interfacial oxide is formed at the interface with the silicon surface. Further, the lattice constant of crystalline materials such as YSZ can be modified by alloying with another compound, such as Al₂O₃. In this way, it is possible to obtain a lattice constant of the crystalline oxide that matches with that of the underlying base substrate material, such as Si. Similarly, the lattice constant of MgO and SrO can also be modified by alloying with other materials.

Additional crystalline oxides can also be deposited to form first buffer layer 12 that require an intermediate template layer between the silicon surface and the crystalline oxide. For example, SrPiO₃ can be epitaxially deposited onto semiconductor substrate 10 after forming a mixed barium oxide and strontium oxide template layer on the silicon surface. Both the template layer and the crystalline oxide layer are preferably formed by oxide molecular beam epitaxy. Under the expitaxial deposition conditions, the crystalline oxide materials align with the silicon substrate such that the inner atomic distances between oxygen and an adjacent metal atom substantially match the silicon-silicon inner atomic distance in the single crystal silicon substrate. Those skilled in the art will appreciate that crystalline oxide materials having different crystalline lattice parameters can be identified that will substantially match the crystalline lattice parameters of other substrates, such as gallium arsenide, germanium, and the like.

After forming first buffer layer 12, second buffer layer 14 is formed to overlie first buffer layer 12, as illustrated in FIG. 2. In one embodiment, second buffer layer 14 is a crystalline oxide material having a crystalline orientation that substantially matches the crystalline orientation of first buffer layer 12. Alternatively, the first and second buffer layers can have differing crystalline orientations. In a preferred embodiment, second buffer layer 14 is a lanthanide oxide, such as Pr₂O₃, Y₂O₃, La₂O₃, and the like. In accordance with the invention, second buffer layer 14 is a material that will align itself with the crystalline orientation of underlying first buffer layer 12, yet will support an overlying silicon layer having a (110) crystalline orientation. In one embodiment of the invention, second buffer layer 14 is deposited by metal organic-chemical-vapor-deposition (MOCVD) using a cold-wall, low-pressure deposition system. The crystalline oxide material of second buffer layer 14 aligns itself with the orientation of the underlying first buffer layer, such that the lattice parameters of second buffer layer 14 substantially match those of underlying first buffer layer 12. Alternatively, second buffer layer 14 can be epitaxially deposited onto first buffer layer 12. Regardless of the particular material, the lattice structure and surface characteristics of second buffer layer 14 are such that an epitaxially grown silicon layer will align with the underlying buffer layer in a (110) crystalline orientation.

Once second buffer layer 14 is formed, a silicon layer 16 is deposited on second buffer layer 14, as illustrated in FIG. 3. In accordance with the invention, a conventional chemical-vapor-deposition (CVD) process can be carried out to deposit silicon layer 16. Silicon layer 16 will align itself to have a (110) crystalline orientation on second buffer layer 14. Accordingly, a silicon layer having a (110) crystalline orientation is deposited on a silicon substrate having a (100) orientation through the use of intermediate buffer layers that align with both (100) silicon and support the formation of (110) silicon. The inventive process can be used, for example, to provide substrates in which both n-type and p-type devices can be formed in substrate regions having either a (110) crystalline orientation or a (100) crystalline orientation. In particular, p-type devices can be formed in silicon regions having a (110) orientation, while n-type devices can be formed in substrate regions having a (100) crystalline orientation.

Those skilled in the art will appreciate that the exact crystalline orientation relationship described above is not essential. The buffer acts as a transfer layer that permits a semiconductor layer to be formed thereon that has a desired crystalline orientation, yet the desired orientation differs from the underlying semiconductor region. Accordingly, the first buffer layer could have a different orientation than the underlying substrate and the second buffer layer could have the same or different orientation from the first buffer layer. All that is required is that the surface upon which the semiconductor layer is formed needs to be such that it will support the desired orientation.

FIG. 4 illustrates, in cross-section, a portion of a semiconductor substrate 20 having already undergone several processing steps in accordance with one embodiment of the invention. In the structure illustrated in FIG. 4, a semiconductor surface 22 is provided having a p-type device region 24 and an n-type device region 26. P-type device region 24 is formed by a thin semiconductor layer 28 that is separated from underlying substrate 20 by a first buffer layer 30 and a second buffer layer 32. N-type device region 26 is an epitaxial semiconductor layer 34 overlying substrate 20. Those skilled in the art will appreciate that various processing methods can be used to fabricate the structure illustrated in FIG. 4. For example, buffer layers 30, 32 and semiconductor layer 28 can be formed on substrate 20, followed by lithographic patterning and etching to form a stack structure in predetermined regions of substrate 20.

Following an etching process to remove unmasked portions of the buffer layers and semiconductor layer, an epitaxial deposition process is carried to epitaxially deposit a semiconductor material in regions of substrate 20 exposed by the patterning and etching process. In accordance with one embodiment of the invention, semiconductor layer 34 is epitaxially deposited to have a crystallographic orientation that substantially matches the crystallographic orientation of substrate 20. In accordance with the processing methods described above, the stack structure forming p-type device region 24 can be fabricated by forming crystalline oxide layers on semiconductor substrate 20 to form buffer layers 30 and 32, followed by deposition of a semiconductor material to form semiconductor layer 28.

As described above, the one or more buffer layers provide a transition region in which a semiconductor material can be formed having a different crystalline orientation than the underlying substrate. In the instant embodiment, semiconductor layer 28 has an orientation that enhances hole conductivity to support the formation of high speed p-type semiconductor devices. Correspondingly, the semiconductor layer 34 has a crystalline orientation that enhances the mobility of electrons, such that high speed n-type semiconductor devices can be formed in n-type region 26.

The semiconductor materials forming substrate 20, and semiconductor layers 28 and 34 can be silicon, gallium arsenide, germanium, and other III-IV semiconductor materials. In a preferred embodiment, substrate 20 is a single crystal silicon substrate having a (100) orientation, semiconductor layer 28 is a deposited silicon layer having a crystalline orientation of (110), and semiconductor layer 34 is an epitaxial silicon layer having a crystalline orientation of (100). In accordance with the processing methods described above, first buffer layer 30 and second buffer layer 32 are crystalline oxide layers having a (100) crystalline orientation.

In addition to the fabrication method described above, the process of the invention can be carried out on a semiconductor substrate in which previous masking and etching steps have been carried out. Selective etching processes are then performed to form regions of a substrate having differing crystallographic orientations. Further, semiconductor regions, such as semiconductor layer 34, can be formed by selective epitaxial deposition processes. The selective deposition process is carried out either by relying upon the underlying substrate surface as a seed layer upon which subsequent layers of semiconductor material are selectively deposited. Alternatively, a seed layer can be deposited and patterned to stimulate the selective deposition of semiconductor material in predetermined regions of the substrate.

The epitaxial deposition process as described above can be carried out in an epitaxial deposition system having a single chamber or having multiple chambers. The first and second buffer layers can be deposited in separate chambers, or alternatively, the buffer layers can be sequentially deposited in a single epitaxial deposition chamber. Further, semiconductor layers overlying the buffer layers can be deposited in a separate deposition chamber or in the same chamber as the underlying buffer layers.

Having described the invention in such detail that one of ordinary skill in the art can fully practice the disclosed invention, the following example is merely illustrative and does not limit the scope of the invention in any way whatsoever.

### EXAMPLE

A (001) silicon wafer is cleaned using a conventional wafer cleaning process and placed into the deposition chamber of an epitaxial deposition apparatus. A Al₂O₃ modified oxide layer containing Zr, Al, and O is grown in the chamber under ultra high vacuum deposition conditions. The process is carried out such that the lattice mismatch between the oxide layer and the substrate is less than about 0.1%. Then, a second oxide layer containing Y, Pr, Zr, and O is grown in the epitaxial deposition apparatus. The surface defect density of the first and second oxide layers is extremely low and substantially below that of layers formed in a conventional epitaxial process. The wafer is then transferred to a CVD deposition system and a layer of (011) Si is deposited using standard CVD operating conditions.

Thus, there have been described a method for fabricating a semiconductor structure having heterogeneous crystalline orientations that fully provides the features and advantages set forth above. Those skilled in the art will appreciate that variations and modifications can be made without departing from the spirit and scope of the invention. For example, various doping processes can be used to change the conductivity type of different regions within the substrate, such as ion implantation, molecular beam implantation, and the like. Further, numerous different types of lithographic patterning and thin film etching techniques can be used to fabricate various device structures and regions within the substrate. Accordingly, all such variations are intended to be included in the appended claims and equivalence thereof.

1. A method for fabricating a semiconductor structure having heterogeneous crystalline orientations comprising:
providing a first region comprising a semiconductor material having a first crystalline orientation;
forming an epitaxial buffer on the first semiconductor region; and
forming a second region of the semiconductor material on the buffer layer, the second region having a second crystalline orientation different from the first crystalline orientation.

2. The method of claim 1, wherein the semiconductor material comprises silicon.

3. The method of claim 1, wherein the semiconductor material comprises a group III-V semiconductor material.

4. The method of claim 1, wherein the semiconductor material comprises silicon gallium arsenide.

5. The method of claim 1, wherein the semiconductor material comprises germanium.

6. The method of claim 1, wherein the semiconductor material comprises silicon having a (100) crystalline orientation and the region comprises silicon having a (011) crystalline orientation.

7. The method of claim 1, wherein forming an epitaxial buffer comprises forming a crystalline oxide material.

8. The method of claim 1, wherein forming an epitaxial buffer comprises forming at least two crystalline oxide layers of differing composition.

9. The method of claim 1, wherein the forming an epitaxial buffer comprises forming a first buffer layer having the same crystalline orientation as the first region and forming a second buffer layer on the first buffer layer.

10. The method of claim 1, wherein forming a second buffer layer comprises forming the second buffer layer having substantially the same crystalline orientation as the first buffer layer.

11. A method for fabricating a semiconductor layer comprising:
providing a semiconductor substrate having a first crystalline orientation;
forming a first crystalline dielectric layer on the semiconductor substrate;
forming a second crystalline dielectric layer on the first crystalline dielectric layer; and
forming a semiconductor region on the second crystalline dielectric layer, the semiconductor substrate having a second crystalline orientation different from the first crystalline orientation.

12. The method of claim 11, wherein forming a first crystalline dielectric layer comprises forming a ceramic material.

13. The method of claim 11, wherein forming a first crystalline dielectric layer comprises forming a ceramic oxide.

14. The method of claim 11, wherein forming a first crystalline dielectric layer comprises forming a ceramic zirconium compound.

15. The method of claim 11, wherein forming a first crystalline dielectric layer comprises one of SrO, ZrO₂, or YSZ.

16. The method of claim 11, wherein forming a second crystalline dielectric layer comprises forming a lanthanide oxide having substantially the same crystalline orientation as the semiconductor substrate.

17. The method of claim 11, wherein providing a semiconductor substrate comprises forming providing a silicon substrate having a (100) crystalline orientation and forming a semiconductor region comprises forming a silicon region having a (011) crystalline orientation.

18. A method for fabricating a semiconductor layer comprising:
providing a semiconductor substrate having a first device region of a first conductivity type and a second device region of a second conductivity type, the semiconductor substrate having a first crystalline orientation;
forming a buffer in at least the first device region; and
forming a semiconductor layer on the buffer, the semiconductor layer having second crystalline orientation different from the first crystalline orientation.

19. The method of claim 18, wherein providing a semiconductor substrate comprises providing a silicon substrate having a (100) crystalline orientation and forming a semiconductor layer comprises forming a silicon layer having a (011) crystalline orientation.

20. The method of claim 18, wherein the forming a buffer comprises epitaxial deposition of a first buffer layer having the same crystalline orientation as the first region and epitaxial deposition of a second buffer layer on the first buffer layer.

21. The method of claim 20, wherein the second buffer layer has substantially the same crystalline orientation as the first buffer layer.

22. The method of claim 18, wherein the substrate comprises a p-type substrate, and wherein the method further comprises forming p-type transistors in the semiconductor layer.

23. The method of claim 18, wherein the substrate comprises an n-type substrate, and wherein the method further comprises forming n-type transistors in the semiconductor layer.
